(19) United States
(12) Patent Application Publication
(10) Pub. No.: US 2023/0187355 A1
(43) Pub. Date: Jun. 15, 2023

(54) Method to Produce Buried Nb Lines Surrounded by Ti

(71) Applicant: International Business Machines Corporation, Armonk, NY (US)

(72) Inventors: Santino Carnevale, Yorktown Heights, NY (US); Wei Kong, Yorktown Heights, NY (US); Mary Beth Rothwell, Yorktown Heights, NY (US); Bryan Trimm, Yorktown Heights, NY (US); Brent Wascaser, Yorktown Heights, NY (US)

(21) Appl. No.: 17/644,448

(22) Filed: Dec. 15, 2021

(51) Int. Cl. H01L 23/532; H01L 21/768

(52) U.S. Cl. CPC H01L 23/53285; H01L 21/7685; H01L 21/76877; H01L 21/7684

(57) ABSTRACT

A method comprising forming a trench in a substrate and forming a first Ti layer on the top surface of the substrate, such that, the first Ti layer is formed on the exposed surface of the trench. Forming a Nb layer on an exposed top surface of first Ti layer and forming a second Ti layer on the exposed top surface of the Nb layer. Planarizing the second Ti layer, the Nb layer, and the first Ti layer to the top surface of the substrate, wherein the second Ti layer, the Nb layer, and the first Ti layer remain within the trench, wherein the Nb layer has at least two surfaces exposed during the planarizing process.

### STATEMENT REGARDING FEDERALLY SPONSORED RESEARCH OR DEVELOPMENT

This invention was made with U.S. Government support. The U.S. Government has certain rights in this invention.

### BACKGROUND

The present invention relates to microelectronics fabrication, and more specifically, to fabrication of Nb lines protected by Ti.

When producing devices with Nb on a silicon substrate having a Ti underlayer or overlayer helps to protect the Nb from oxidation and in certain circumstances improves device performance. A Nb device fully surrounded by Ti is most desirable since it provides the best protection against oxidation of the Nb device. However, typical during fabrication the vacuum needs to be broken one or more times when forming the different layers, thus oxidation occurs when the vacuum is broken.

### BRIEF SUMMARY

Additional aspects and/or advantages will be set forth in part in the description which follows and, in part, will be apparent from the description, or may be learned by practice of the invention.

A method comprising forming a trench in a substrate and forming a first Ti layer on the top surface of the substrate, such that, the first Ti layer is formed on the exposed surface of the trench. Forming a Nb layer on an exposed top surface of first Ti layer and forming a second Ti layer on the exposed top surface of the Nb layer. Planarizing the second Ti layer, the Nb layer, and the first Ti layer to the top surface of the substrate, wherein the second Ti layer, the Nb layer, and the first Ti layer remain within the trench, wherein the Nb layer has at least two surfaces exposed during the planarizing process.

An apparatus comprising a trench located in a substrate and an underlayer is located on top of the substrate within the trench and along the sidewalls of the trench. A device layer is located on top of the underlayer within the trench and an overlayer is located on top of the device layer within the trench. Wherein an exposed top surface device layer is sandwiched between an exposed surface of the underlayer and an exposed surface of the overlayer.

A method comprising forming a trench in a substrate and forming a first Ti layer on the top surface of the substrate, such that, the first Ti layer is formed on the exposed surface of the trench, wherein the first Ti layer has a thickness T1. Forming a Nb layer on an exposed top surface of first Ti layer, wherein the Nb layer has a thickness T2, wherein the depth of the trench is greater than the sum of thickness T1 and T2. Forming a second Ti layer on the exposed top surface of the Nb layer, wherein the second Ti layer has a thickness T3, wherein the depth of the trench is less than the sum of thickness Ti, T2, and T3. Planarizing the second Ti layer, the Nb layer, and the first Ti layer to the top surface of the substrate, wherein the second Ti layer, the Nb layer, and the first Ti layer remain within the trench, wherein the Nb layer has at least two surfaces exposed during the planarizing process.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 represents a cross sectional view depicting a substrate, according to an example embodiment;

FIG. 2 represents a cross sectional view depicting the formation of a trench in the substrate, according to an example embodiment;

FIG. 3 represents a cross sectional view depicting the formation of the underlayer, according to an example embodiment;

FIG. 4 represents a cross sectional view depicting the formation of the Nb line, according to an example embodiment;

FIG. 5 represents a cross sectional view depicting the formation of the overlayer, according to an example embodiment;

FIG. 6 represents a cross sectional view depicting the device after planarization, according to an example embodiment.

Elements of the figures are not necessarily to scale and are not intended to portray specific parameters of the invention. For clarity and ease of illustration, dimensions of elements may be exaggerated. The detailed description should be consulted for accurate dimensions. The drawings are intended to depict only typical embodiments of the invention, and therefore should not be considered as limiting the scope of the invention. In the drawings, like numbering represents like elements.

### DETAILED DESCRIPTION

Exemplary embodiments now will be described more fully herein with reference to the accompanying drawings, in which exemplary embodiments are shown. This disclosure may, however, be embodied in many different forms and should not be construed as limited to the exemplary embodiments set forth herein. Rather, these exemplary embodiments are provided so that this disclosure will be thorough and complete and will convey the scope of this disclosure to those skilled in the art. In the description, details of well-known features and techniques may be omitted to avoid unnecessarily obscuring the presented embodiments.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements. As used herein, the term “same” when used for comparing values of a measurement, characteristic, parameter, etc., such as “the same width,” means nominally identical, such as within industry accepted tolerances for the measurement, characteristic, parameter, etc., unless the context indicates a different meaning. As used herein, the terms “about,” “approximately,” “significantly, or similar terms, when used to modify physical or temporal values, such as length, time, temperature, quantity, electrical characteristics, superconducting characteristics, etc., or when such values are stated without such modifiers, means nominally equal to the specified value in recognition of variations to the values that can occur during typical handling, processing, and measurement procedures. These terms are intended to include the degree of error associated with measurement of the physical or temporal value based upon the equipment available at the time of filing the application, or a value within accepted engineering tolerances of the stated value. For example, the term “about” or similar can include a range of ±8% or 5%, or 2% of a given value. In one aspect, the term “about” or similar means within 10% of the specified numerical value. In another aspect, the term “about” or similar means within 5% of the specified numerical value. Yet, in another aspect, the term “about” or similar means within 10, 9, 8, 7, 6, 5, 4, 3, 2, or 1% of the specified numerical value. In another aspect, these terms mean within industry accepted tolerances.

For the clarity of the description, and without implying any limitation thereto, illustrative embodiments may be described using simplified diagrams. In an actual fabrication, additional structures that are not shown or described herein, or structures different from those shown and described herein, may be present without departing from the scope of the illustrative embodiments.

Differently patterned portions in the drawings of the example structures, layers, and formations are intended to represent different structures, layers, materials, and formations in the example fabrication, as described herein. A specific shape, location, position, or dimension of a shape depicted herein is not intended to be limiting on the illustrative embodiments unless such a characteristic is expressly described as a feature of an embodiment. The shape, location, position, dimension, or some combination thereof, are chosen only for the clarity of the drawings and the description and may have been exaggerated, minimized, or otherwise changed from actual shape, location, position, or dimension that might be used in actual fabrication to achieve an objective according to the illustrative embodiments.

An embodiment when implemented in an application causes a fabrication process to perform certain steps as described herein. The steps of the fabrication process are depicted in the several figures. Unless such a characteristic is expressly described as a feature of an embodiment, not all steps may be necessary in a particular fabrication process; some fabrication processes may implement the steps in different order, combine certain steps, remove or replace certain steps, or perform some combination of these and other manipulations of steps, without departing the scope of the illustrative embodiments.

The illustrative embodiments are described with respect to certain types of materials, electrical properties, structures, formations, layers orientations, directions, steps, operations, planes, dimensions, numerosity, data processing systems, environments, and components. Unless such a characteristic is expressly described as a feature of an embodiment, any specific descriptions of these and other similar artifacts are not intended to be limiting to the invention; any suitable manifestation of these and other similar artifacts can be selected within the scope of the illustrative embodiments.

The illustrative embodiments are described using specific designs, architectures, layouts, schematics, and tools only as examples and are not limiting to the illustrative embodiments. The illustrative embodiments may be used in conjunction with other comparable or similarly purposed designs, architectures, layouts, schematics, and tools.

For the sake of brevity, conventional techniques related to microelectronic fabrication may or may not be described in detail herein. Moreover, the various tasks and process steps described herein can be incorporated into a more comprehensive procedure or process having additional steps or functionality not described in detail herein. In particular, various steps in the manufacture of microelectronic devices may be well known and so, in the interest of brevity, many conventional steps may only be mentioned briefly or may be omitted entirely without providing the well-known process details.

In the following descriptions, the term length applies to dimensional characteristics along the x-axis.

In the following descriptions, the term width applies to dimensional characteristics along the y-axis.

In the following descriptions, the term thickness applies to dimensional characteristics along the z-axis.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Various processes used to form a micro-chip that will be packaged into an integrated circuit (IC) fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

Reference will now be made in detail to the embodiments of the present invention, examples of which are illustrated in the accompanying drawings, wherein like reference numerals refer to like elements throughout. Embodiments of the invention are generally directed to formation of a Nb device, for example, a Nb line, that is almost completely enclosed by an underlayer and overlayer of Ti. The presenting invention is directing towards forming the underlayer, the Nb line, and the overlayer without breaking vacuum to minimize oxidation formation by prevent the device from being exposed to air. Furthermore, the Nb device is formed without the need to utilize a subtractive etching process, thus preventing damage to the Nb device from the etching process.

Depositing Ti—Nb—Ti on flat blanket layers and then subtractively removing the Ti—Nb—Ti in areas where it is not wanted can cause defects and leaves the sidewalls of the Nb are exposed. With the subtractive etching processes the area (the sidewalls of the Ti—Nb—Ti) is exposed successively and is present during the reactive ion etching (RIE) process and during resist removal and the clean-up chemicals. Also, it is difficult do to the dissimilarities of Ti, Nb, and Si to develop processes that are compatible with Ti, Nb and Si. For example, HF is commonly used to remove oxides from both Nb and Si, but the etch rate of Ti is very rapid in HF, so when HF is used the underlayer of Ti is removed detaching the Nb layers from the Si surface.

The present invention utilizes chemical mechanical planarization CMP to exposed the different layers simultaneously. Furthermore, by utilizing a CMP process the device exposure to different chemicals that are harmful to the layers is minimized. The present invention removes a need for a second lithography process for removing the excess materials of the different layers, since the present invention is able to remove excess material with a blanket removal process (i.e., CMP)

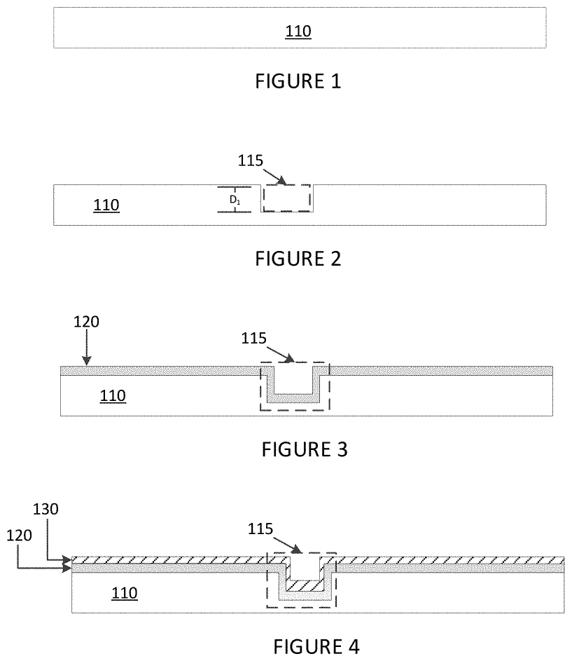

FIG. 1 represents a cross sectional view depicting a substrate 110, according to an example embodiment. The substrate 110 can be, for example, a Si wafer or some other appropriate material. FIG. 2 represents a cross sectional view depicting the formation of a trench 115 in the substrate 110, according to an example embodiment. The substrate 110 is etched by, for example, RIE to form trench 115. The substrate 110 is pattern to determine where the trench 115 will be formed and the etching process determines the depth Di of the trench 115 (e.g., how far the trench 115 extends downwards). The trench 115 has a depth Di that is greater than the desired thickness of the underlayer of Ti, the thickness of the Nb layer, and a thickness of a portion of the overlayer of Ti.

FIG. 3 represents a cross sectional view depicting the formation of the underlayer 120, according to an example embodiment. The underlayer 120 is formed on top of the substrate 110 and along the walls of the trench 115. The underlayer 120 can be comprised of, for example, Ti. The underlayer 120 can be formed by, for example, ALD, CVD, spin coating, or another deposition technique. The underlayer 120 has a thickness in the range of about 1 to 20 nm.

FIG. 4 represents a cross sectional view depicting the formation of the Nb line, according to an example embodiment. A Nb layer 130 is formed on top of the underlayer 120. The thickness of the Nb layer 130 can be in the range of about 50 to 1000 nm. The design for the Nb line will determine the desired thickness of the Nb layer 130. Therefore, the depth Di of the trench 115 is greater than the combined thickness of the underlayer 120 and the Nb layer 130. The depth Di needs to be greater than the combined thickness of the underlayer 120 and the Nb layer 130 to allow for the formation of a portion of the overlayer 140 to be located within the trench 115.

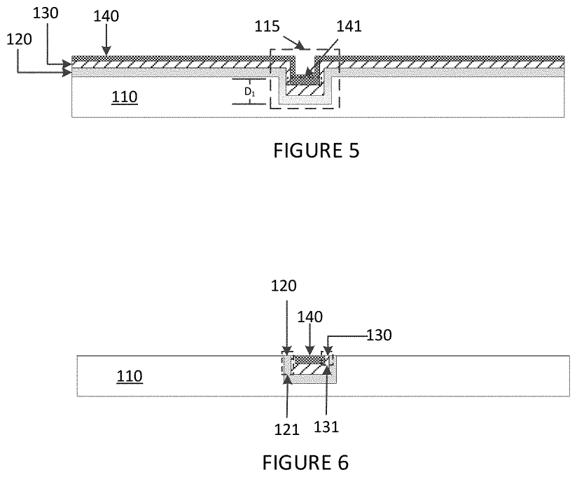

FIG. 5 represents a cross sectional view depicting the formation of the overlayer 140, according to an example embodiment. The overlayer 140 is formed on the top surface of Nb layer 130. The amount of material deposited to form the overlayer 140 exceeds the amount of space still available within the trench 115 prior to the formation of the overlayer 115. The over deposition of the overlayer 140 guarantees the remaining available space within the trench 115 is filled with the material for the overlayer 140. A portion as indicated by dashed box 141 of the overlayer 140 is located within the trench 115. As FIG. 5 illustrates the thickness of the overlayer 140 is greater than the space available within the trench 115 (as dashed box 141 illustrates). Therefore, the depth Di of the trench 115 must be large enough the accommodate the combined thickness of the underlayer 120, the Nb layer 130 and a portion of the overlayer 140. Also, the depth Di of the trench 115 must be less than the combined thickness of the underlayer 120, the Nb layer 130 and the overlayer 140. The Nb layer 130 is sandwiched between the underlayer 120 and the overlayer 140.

FIG. 6 represents a cross sectional view depicting the device after planarization, according to an example embodiment. The overlayer 140, the Nb layer 130, and the underlayer 120 are planarized by, for example, chemical-mechanical planarization (CMP). The CMP process removes the excess material of each of the underlayer 120, the Nb layer 130, and the overlayer 140. The CMP process simultaneously exposes a surface of the underlayer 120, a surface of the Nb layer 130, and a surface of the overlayer 140. The CMP process reduces the thickness of the overlayer 140, such that only a portion of the overlayer 140 located within the trench 115 is remaining after the CMP process. The underlayer 120 has a horizontal portion that extends across the bottom of the trench 115 and vertical portions 121 that extend up the vertical sidewalls of the trench 115. The top surface of the vertical portions 121 of the underlayer 120 are planar with the top surface of the substrate 110. The Nb layer 130 has a horizontal section along the top of the horizontal portion of the underlayer 120 and the Nb layer 130 has vertical sections 131 that extend up the vertical portions of the underlayer 120. Each vertical section 131 is adjacent to one of the vertical portions 121 of the underlayer 120. The top surface of each of the vertical sections 131 is planar with the top surface of the substrate 110 and the top surface of the vertical portions 121 of the underlayer 120. The overlayer 140 extends across the horizontal section of the Nb layer 130, where each of the vertical sections 131 of the Nb layer 121 is adjacent to a sidewall of the overlayer 140. The vertical height of each of the vertical sections 131 is equal to the thickness of the overlayer 140, as measured from the top of the horizontal section to the top of the vertical section 131 of the Nb layer 130. The vertical height (as measured from the top of the horizontal portion to the top of the vertical portion 121 of the underlayer 120) of each of the vertical portions 121 of the underlayer 120 is equal to the combined thickness of the horizontal portion of the Nb layer 130 and the thickness of the overlayer 140. The top surface of the overlayer 140 is planar with the top surfaces of vertical sections 131 of the Nb layer 130, the top surface of the vertical portions 121 of the underlayer 120, and the top surface of the substrate 110.

By doing an initial etch of the substrate 110 to form the trench 115 allows for the formation of each of the underlayer 120, the Nb layer 120, and the overlayer 130 within the trench 115. The formation of each of the layers is done one after the other within the same processing environment, thus preventing the need for the device to be removed from vacuum during the layer formation. This process prevents/minimizes the oxidation of the underlayer 120, the Nb layer 130, and the overlayer 140 by maintaining the vacuum while forming each of the individual layers. Furthermore, by utilizing the trench 115 to form the Nb lines, then the excess materials of the underlayer 120, the Nb layer 130, and the overlayer 140 can be removed by a CMP process, thus preventing the use of different lithographic chemicals or methods that could damage the final layers.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A method comprising:
forming a trench in a substrate;
forming a first Ti layer on the top surface of the substrate, such that, the first Ti layer is formed on the exposed surface of the trench;
forming a Nb layer on an exposed top surface of first Ti layer;
forming a second Ti layer on the exposed top surface of the Nb layer; and
planarizing the second Ti layer, the Nb layer, and the first Ti layer to the top surface of the substrate, wherein the second Ti layer, the Nb layer, and the first Ti layer remain within the trench, wherein the Nb layer has at least two surfaces exposed during the planarizing process.

2. The method of claim 1, wherein the first Ti layer, the Nb layer, and the second Ti layer are sequentially formed without breaking vacuum.

3. The method of claim 1, wherein the trench has a depth greater than a thickness of the first Ti layer combined with a thickness of the Nb layer.

4. The method of claim 2, wherein the depth of the trench is less than the combined thickness of the first Ti layer, the Nb layer, and the second Ti layer.

5. The method of claim 4, wherein a first portion of the second Ti layer is contained within the trench while a second portion of the second Ti layer extends above the trench.

6. The method of claim 1, wherein the planarization of the first Ti layer, the Nb layer, and the second Ti layer simultaneously exposes a top surface of the first Ti layer, the at least two top surfaces of the Nb layer, and a top surface of the second Ti layer.

7. An apparatus comprising:
a trench located in a substrate;
an underlayer is located on top of the substrate within the trench and along the sidewalls of the trench;
a device layer is located on top of the underlayer within the trench;
an overlayer is located on top of the device layer within the trench;
wherein an exposed top surface device layer is sandwiched between an exposed surface of the underlayer and an exposed surface of the overlayer.

8. The apparatus of claim 7, wherein the exposed surfaces of the underlayer, the device layer, and the overlayer are planar with the top surface of the substrate.

9. The apparatus of claim 7, wherein the underlayer is comprised of Ti.

10. The apparatus of claim 7, wherein the device layer is comprised of Nb.

11. The apparatus of claim 7, wherein the overlayer is comprised of Ti.

12. The apparatus of claim 7, wherein the underlayer has a horizontal portion and at least two vertical portions.

13. The apparatus of claim 12, wherein the device layer has a horizontal section and at least two vertical sections.

14. The apparatus of claim 13, wherein the overlayer has a horizontal portion.

15. The apparatus of claim 14, wherein each vertical section of the device layer is sandwiched between a vertical portion of the underlayer and the horizontal portion of the overlayer.

16. A method comprising:
forming a trench in a substrate;
forming a first Ti layer on the top surface of the substrate, such that, the first Ti layer is formed on the exposed surface of the trench, wherein the first Ti layer has a thickness Ti;
forming a Nb layer on an exposed top surface of first Ti layer, wherein the Nb layer has a thickness T2, wherein the depth of the trench is greater than the sum of thickness T1 and T2;
forming a second Ti layer on the exposed top surface of the Nb layer, wherein the second Ti layer has a thickness T3, wherein the depth of the trench is less than the sum of thickness Ti, T2, and T3; and
planarizing the second Ti layer, the Nb layer, and the first Ti layer to the top surface of the substrate, wherein the second Ti layer, the Nb layer, and the first Ti layer remain within the trench, wherein the Nb layer has at least two surfaces exposed during the planarizing process.

17. The method of claim 16, wherein the first Ti layer, the Nb layer, and the second Ti layer are sequentially formed without breaking vacuum.

18. The method of claim 16, wherein the planarization of the first Ti layer, the Nb layer, and the second Ti layer simultaneously exposes a top surface of the first Ti layer, the at least two top surfaces of the Nb layer, and a top surface of the second Ti layer.

19. The method of claim 18, wherein after planarization the first Ti layer has a horizontal portion and at least two vertical portions.

20. The method of claim 19, wherein after planarization the Nb layer has a horizontal section and at least two vertical sections, and wherein after planarization the second Ti has a horizontal portion.
